(19) United States
(12) Patent Application Publication
(10) Pub. No.: US 2008/0023765 A1
(43) Pub. Date: Jan. 31, 2008

(54) Semiconductor Devices and Methods of Fabricating the Same

(75) Inventors: Taek-Soo Jeon, Yongin-si (KR); In-Sang Kang, Seoul (KR); Sang-Bom Kang, Seoul (KR); Hong-Bae Park, Gyeyang-gu (KR); Hag-Ju Cho, Yongin-si (KR); Hye-Lan Lee, Hwaseong-si (KR)

Correspondence Address: MYERS BIGEL SIBLEY & SAJOVEC, PO BOX 37428, RALEIGH, NC, 27627, US

(73) Assignee: Samsung Electronics Company, Ltd.

(21) Appl. No.: 11/756,122

(22) Filed: May 31, 2007

(30) Foreign Application Priority Data
Jun. 1, 2006 (KR) 10-2006-0049470

(51) Int. Cl. H01L 27/01; H01L 21/00

(52) U.S. Cl. 257/350; 438/199; 257/E21.001; 257/E21.177

(57) ABSTRACT

Provided are semiconductor devices and methods of fabricating the semiconductor devices. Embodiments of such methods may include sequentially forming a gate insulation layer and a metal layer on a semiconductor substrate and etching the metal layer to form a metallic residue on the gate insulation layer. Such methods may also include monitoring an etch by-product to detect an etch endpoint for stopping the etching and forming a polysilicon layer on the gate insulation layer including the metallic residue.

### CROSS-REFERENCE TO RELATED APPLICATIONS

This U.S. non-provisional patent application claims priority under 35 U.S.C. § 119 of Korean Patent Application No. 2006-49470, filed on Jun. 1, 2006, the entire contents of which are hereby incorporated by reference.

### BACKGROUND OF THE INVENTION

The present invention relates to semiconductor devices and a methods of fabricating semiconductor devices.

Many highly-integrated semiconductor devices may use a metal oxide silicon field effect transistor (MOSFET) as an active device. A MOSFET may include a pair of source/drain electrodes formed on a semiconductor substrate, a gate insulation layer, and a gate electrode. The gate insulation layer and the gate electrode may be sequentially formed in a channel region (i.e., a region of the semiconductor substrate between the source/drain electrodes). An electrical resistance of the channel region may be adjusted by a voltage applied to the gate electrode. For example, when a voltage (hereinafter, referred to as a gate voltage) applied to the gate electrode is higher than a threshold voltage Vₜₕ, a channel may be formed in the channel region to electrically connect the source/drain electrodes. In contrast, when the gate voltage is lower than the threshold voltage Vₜₕ, the source/drain electrodes may be electrically disconnected. Since the electric resistance of the channel region may be controlled by the gate voltage, the MOSFET may be used for a logic circuit or a switch device of a semiconductor device.

MOSFETs may be classified into an NMOS-FET and a PMOS-FET according to the doping type of a channel region. The NMOS-FET may use electrons as majority carriers, and the PMOS-FET may use holes as majority carriers. Thus, the NMOS-FET can have an operation speed faster than that of the PMOS-FET. In a complementary metal oxide silicon (CMOS) type semiconductor device, both the NMOS-FET and the PMOS-FET may be used to reduce operation voltages and power consumption.

Since work functions of some CMOS type semiconductor devices may be adjusted to a desired level by changing a dopant or the concentration of the dopant, impurity-doped polysilicon may be used as a gate electrode material for the CMOS type semiconductor devices. However, since gate depletion may increasingly occur as the integration level of semiconductor devices increases, conventional polysilicon gate MOSFETs may be no longer suitable for highly-integrated semiconductor devices. For example, when polysilicon is used for a gate electrode, a depletion region may be generated due to a gate voltage applied to the gate electrode to turn on a channel region. The depletion region may act as an additional capacitor connected in series to a MOS capacitor, and thus the total capacitance of a MOSFET may decrease. As a result, as shown in FIG. 1, a capacitance-voltage curve of an NMOS-FET may be deformed by gate poly depletion when the gate voltage (V) is high.

To address this gate depletion, a metal layer may be used as a gate electrode in a metal gate MOSFET. The metal ions of the metal layer may, however, deteriorate the characteristics of a gate insulation layer. Additionally, the work function of the metal layer may not be as easily controlled as that of, for example, polysilicon. In some cases, it may be beneficial for a CMOS type semiconductor device to have gate work functions of an NMOS-FET around 4.1 eV and in a PMOS-FET around 5.2 eV. As such, gate electrodes of the NMOS-FET and the PMOS-FET may be formed of different metals. Further, since metals may have melting points lower than that of silicon, the process temperatures of subsequent processes may have to be lower than the melting point of a metal used for a gate electrode. In this manner, the metal gate MOSFET may require more complicated manufacturing processes as compared with those for a polysilicon gate MOSFET. Additionally, process temperature ranges may be more restrictive.

### SUMMARY OF THE INVENTION

The present invention provides semiconductor devices and methods of fabricating semiconductor devices. Embodiments of methods for fabricating a semiconductor device may include forming a gate insulation layer on a semiconductor substrate, forming a metal layer on the gate insulation layer, etching the metal layer to leave a metallic residue on the gate insulation layer, monitoring an etch by-product to detect an etch endpoint for stopping the etching, and forming a polysilicon layer on the gate insulation layer having the metallic residue.

In some embodiments, etching the metal layer includes leaving 1% to 100% of a top area of the gate insulation area with the metallic residue. In some embodiments, etching the metal layer includes leaving metallic residue islands spaced apart from each other to expose a top surface of the gate insulation layer. In yet some embodiments, etching the metal layer includes defining a plurality of openings in the metallic residue through which a top surface of the gate insulation layer is exposed. In some embodiments, etching the metal layer includes leaving the metallic residue in a thickness of about 2 Å to about 10 Å on a top surface of the gate insulation layer.

Some embodiments may include prior to etching the metal layer, heat-treating the metal layer to form an interface metal layer between the metal layer and the gate insulation layer, the interface metal layer having a chemical composition ratio different from that of the metal layer, wherein the interface metal layer is formed by a reaction between the metal layer and the gate insulation layer during the heat-treatment.

In some embodiments, forming the metal layer includes depositing one of TaN, WN, TiN, Ta, W, Ti, Ru, HfN, HfSiN, TiSiN, TaSiN, and HfAIN on the gate insulation layer using one of PVD (physical vapor deposition), CVD (chemical vapor deposition), and ALD (atomic layer deposition).

In some embodiments, the semiconductor substrate includes an NMOS (n-type metal oxide silicon) region and a PMOS (p-type metal oxide silicon) region. In such embodiments, forming the polysilicon layer may include implanting first and second dopants into the NMOS and PMOS regions, respectively. In some embodiments, the first dopants implanted into the NMOS include a first doping concentration, the second dopants implanted into PMOS regions include a second doping concentration, and the first dopant concentration is different from the second doping concentration.

Some embodiments include, after forming the polysilicon layer, forming an upper conductive layer on the polysilicon layer, patterning the upper conductive layer and the polysilicon layer to form a gate electrode, and forming drain/source regions in the semiconductor substrate at both sides of the gate electrode. In some embodiments, the upper conductive layer is formed of a silicide layer or an upper metal layer.

Some embodiments of the present invention include semiconductor devices. Embodiments of such devices may include a semiconductor substrate including an NMOS region and a PMOS region, polysilicon electrodes disposed on the semiconductor substrate in the NMOS and PMOS regions, a gate insulation layer disposed between the semiconductor substrate and the polysilicon electrodes, and a metallic residue disposed between the gate insulation layer and the polysilicon electrodes.

In some embodiments, the metallic residue covers 1% to 100% of a top area of the gate insulation layer. In some embodiments, the metallic residue includes islands that are spaced apart from each other to expose a top surface of the gate insulation layer. In some embodiments, the metallic residue includes multiple openings through which a top surface of the gate insulation layer is exposed. In some embodiments, the metallic residue covers a top surface of the gate insulation layer to a thickness of 2 Å to 10 Å.

In some embodiments, the metallic residue is formed of a material selected from the group consisting of TaN, WN, TiN, Ta, W, Ti, Ru, HfN, HfSiN, TiSiN, TaSiN, and HfAIN. In some embodiments, the metallic residue is formed by reacting the gate insulation layer with a material selected from the group consisting of TaN, WN, TiN, Ta, W. Ti, Ru, HfN, HfSiN, TiSiN, TaSiN, and HfAIN.

In some embodiments, the polysilicon electrode formed in the NMOS region includes a first dopant type and a first concentration and the polysilicon electrode formed in the PMOS region includes a second dopant type and a second dopant concentration. In some embodiments, the first dopant type is different from the second dopant type and the first dopant concentration is different from the second dopant concentration.

### BRIEF DESCRIPTION OF THE FIGURES

FIG. 1 is a graph illustrating the effect of polysilicon-gate depletion.

FIG. 2 is a flowchart illustrating operations for fabricating a semiconductor device according to some embodiments of the present invention.

FIGS. 3 through 6 are sectional views illustrating methods of fabricating semiconductor devices according to some embodiments of the present invention.

FIGS. 7A through 7C are plan views illustrating operations for forming a metal residue in method of fabricating a semiconductor device according to some embodiments of the present invention.

FIGS. 8 and 9 are graphs illustrating electric characteristics of gate structures of semiconductor devices according to some embodiments of the present invention.

### DETAILED DESCRIPTION OF PREFERRED EMBODIMENTS

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present invention. In addition, as used herein, the singular forms “a”, “an” and “the” are intended to include the plural forms as well, unless the context clearly indicates otherwise. It also will be understood that, as used herein, the term “comprising” or “comprises” is open-ended, and includes one or more stated elements, steps and/or functions without precluding one or more unstated elements, steps and/or functions. The term “and/or” includes any and all combinations of one or more of the associated listed items.

It will also be understood that when an element is referred to as being “connected” to another element, it can be directly connected to the other element or intervening elements may be present. In contrast, when an element is referred to as being “directly connected” to another element, there are no intervening elements present. It will also be understood that the sizes and relative orientations of the illustrated elements are not shown to scale, and in some instances they have been exaggerated for purposes of explanation. Like numbers refer to like elements throughout.

In the figures, the dimensions of structural components, including layers and regions among others, are not to scale and may be exaggerated to provide clarity of the concepts herein. It will also be understood that when a layer (or layer) is referred to as being ‘on’ another layer or substrate, it can be directly on the other layer or substrate, or can be separated by intervening layers. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

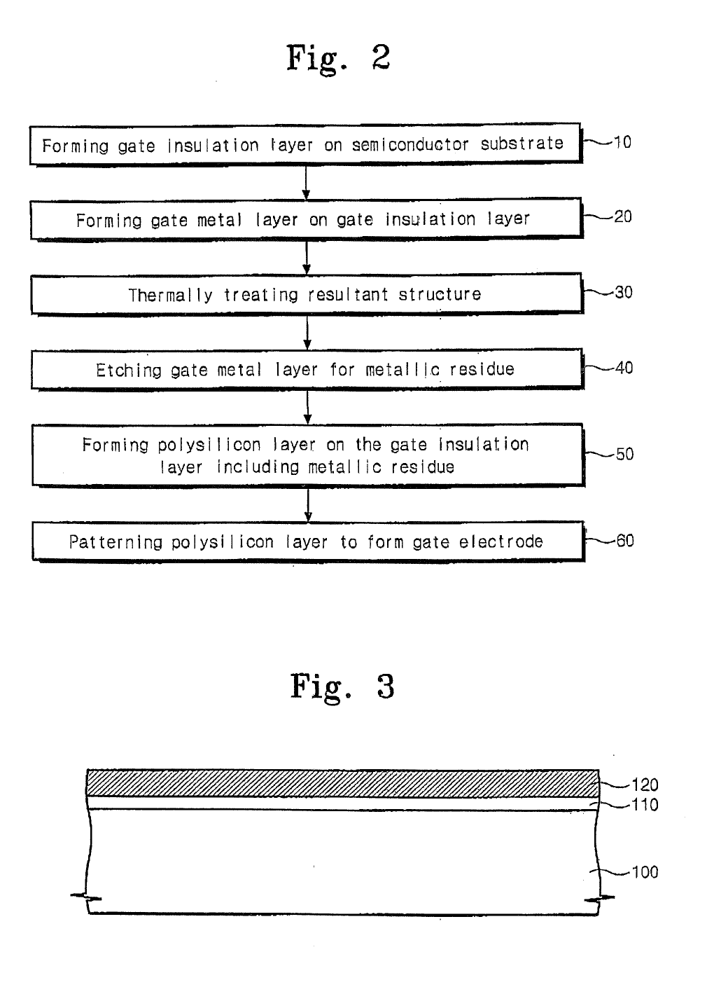

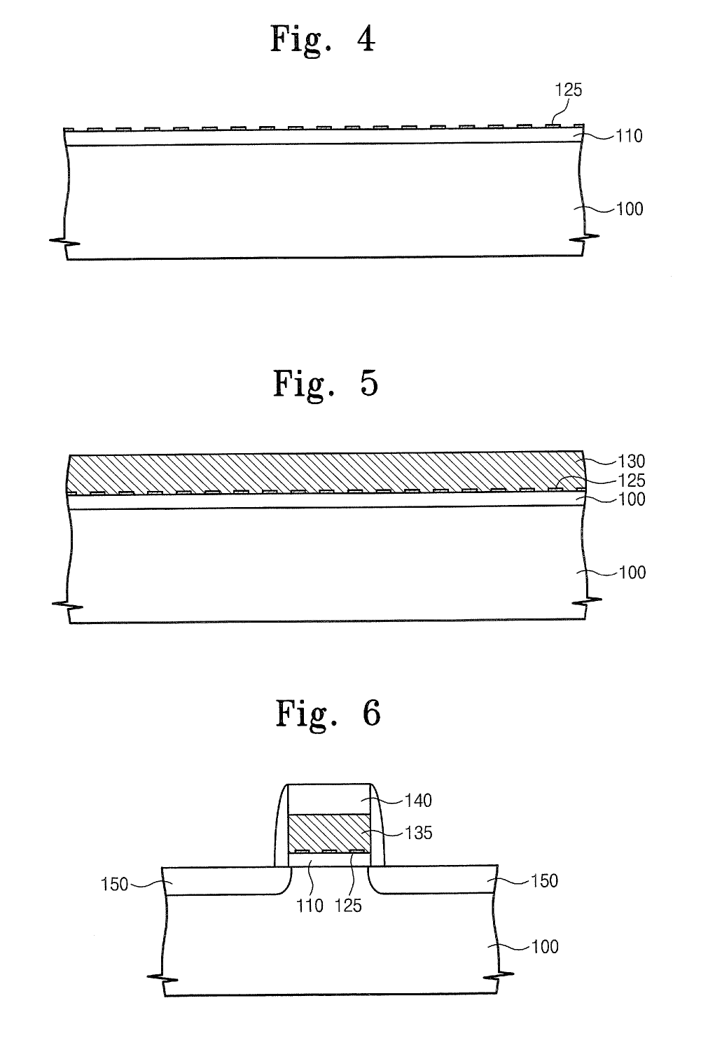

Reference is now made to FIG. 2, which is a flowchart illustrating methods of fabricating semiconductor devices according to some embodiments of the present invention, and FIGS. 3 through 6, which are sectional views for explaining methods of fabricating semiconductor device according to the present invention.

Referring to FIGS. 2 and 3, a gate insulation layer 110 is formed on a semiconductor substrate 100 (block 10) and a gate metal layer 120 is formed on the gate insulation layer 110 (block 20).

The semiconductor substrate 100 may be formed of a semiconductor material (e.g., single crystal silicon). The semiconductor substrate 100 may include an NMOS region and a PMOS region. P-wells including p-type dopants may be formed in the NMOS region, and n-wells including n-type dopants are formed in the NMOS region.

According to the current embodiment of present invention, the gate insulation layer 110 may be formed of a SiO₂ layer and/or high-k dielectric layer. In some embodiments, the high-k dielectric layer may be a SiON layer, HfO₂ layer, HfSiO layer, HfSiON layer, HfON layer, HfAlO layer, HfLaO layer, or La₂O₃ layer. The gate insulation layer 110 may be formed by chemical vapor deposition (CVD) and/or atomic layer deposition (ALD).

The gate metal layer 120 may be formed of one of a variety of metallic materials. For example, in some embodiments, the gate metal layer 120 may be formed of TaN, WN, TiN, Ta, W. Ti, Ru, HfN, HfSiN, TiSiN, TaSiN, and/or HfAIN. The gate metal layer 120 may be formed by, for example, physical vapor deposition (PVD), CVD, and/or ALD. In some embodiments, the gate metal layer 120 may have a thickness of 10 Å to 500 Å.

Referring to FIGS. 2 and 4, the gate metal layer 120 is selectively etched to leave a metallic residue 125 at an interface between the gate insulation layer 110 and the gate metal layer 120 (block 40).

In some embodiments, etching the gate metal layer 120 may be selectively etched using an etch recipe having an etch selectivity with respect to the gate insulation layer 110. In some embodiments, leaving the metallic residue 125 on the gate insulation layer 110 after etching the gate metal layer 120 may be accomplished by adjusting the etch time. In some embodiments, an etch endpoint may be strictly detected. For example, in some embodiments, the etch endpoint may be detected by monitoring the variation of composition of an etch by-product, which may result from an exposure of the gate insulation layer 110.

In addition to forming the gate metal layer 120 on the gate insulation layer 110, an interface metal layer (not shown) may be formed between the gate metal layer 120 and the gate insulation layer 110 by virtue of a reaction. In some embodiments, the interface metal layer may be formed by a reaction between the gate metal layer 120 and the gate insulation layer 110. In this regard, the interface metal layer may have a chemical composition ratio different from that of the gate metal layer 120 (formed above the interface metal layer). For example, if the gate metal layer 120 is formed of TaN and the gate insulation layer 110 is formed of a silicon oxide, the interface metal layer may be a TaON, TaSiN, and/or TaSiON layer. According to some embodiments, the metallic residue 125 may be formed by selective etching that may result from a chemical composition difference between the gate metal layer 120 and the interface metal layer. In this case, the metallic residue 125 may be formed from the gate metal layer 120 and/or the interface metal layer.

According to some embodiments, as shown in FIG. 2, before the gate metal layer 120 is etched, the semiconductor substrate 100 including the gate metal layer 120 may be thermally treated (block 30). The heat treatment may be performed at about 100° C. to 1000° C. for 1 to 10 minutes. Although the heat treatment may be performed for the reaction between the gate metal layer 120 and the gate insulation layer 110, in some embodiments, the reaction may occur without such heat treatment. In this sense, in some embodiments, heat treatment may be an optional operation.

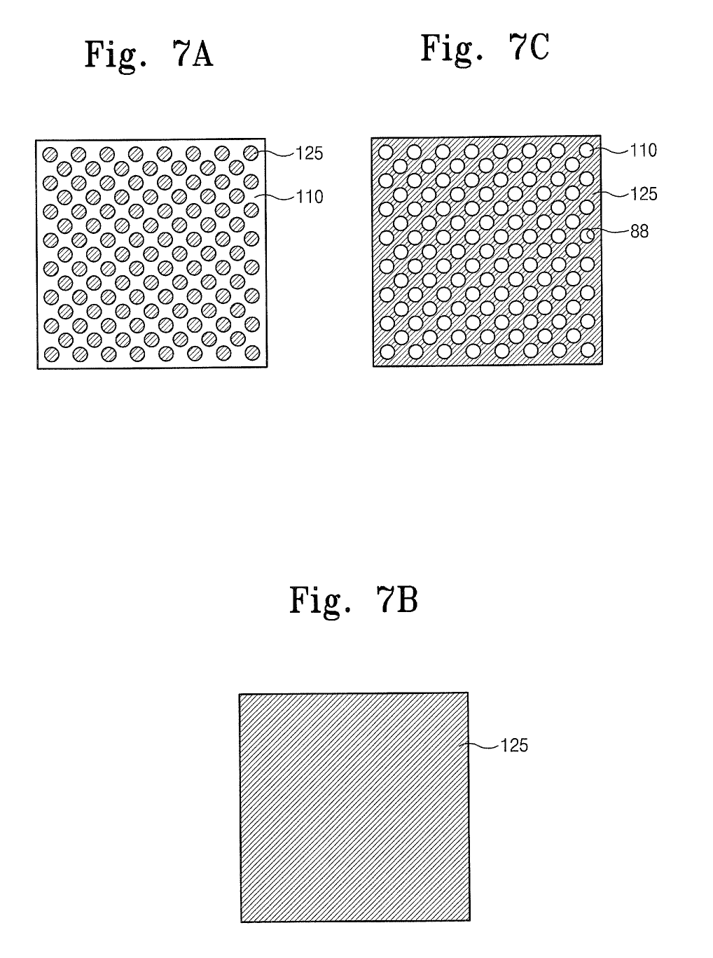

According to some embodiments, the metallic residue 125 may cover 1% to 100% of the top area of the gate insulation layer 110. For example, reference is now made to FIGS. 7A through 7C, which are plan views that illustrate forming the metallic residue 125 in more detail according to some embodiments of the present invention.

Referring to FIG. 7A, some embodiments may provide that the metallic residue 125 may include islands that are spaced apart from each other to expose the top surface of the gate insulation layer 110. In such embodiments, the metallic residue 125 may cover, for example, about 1% to 60% of the top area of the gate insulation layer 110.

Referring to FIG. 7B, some embodiments may provide that the metallic residue 125 may cover the entire top surface of the gate insulation layer 110. In such embodiments, the metallic residue 125 may have a thickness of, for example, about 2 Å to 10 Å and cover about 100% of the top area of the gate insulation layer 110. In this manner, the metallic residue 125 may be formed by etching the gate metal layer 120.

Referring to FIG. 7C, some embodiments may provide that the metallic residue 125 may include openings 88 through which the top surface of the gate insulation layer 110 is exposed. In contrast with embodiments illustrated in FIG. 7A, in some embodiments, the metallic residue 125 may include island openings 88. In such embodiments, the metallic residue 125 may cover, for example, about 30% to 90% of the top area of the gate insulation layer 110.

Reference is now made to FIGS. 2 and 5, in which a polysilicon layer 130 may be formed on the gate insulation layer 110 including the metallic residue 125 (block 50). In some embodiments, the polysilicon layer 130 may be formed by CVD using, for example, silane (SiH₄) and/or disilane (Si₂H₆) as a process gas. In some embodiments, forming the polysilicon layer 130 may include doping the polysilicon layer 130. Doping the polysilicon layer 130 may be performed by, for example, an ion implantation and/or in-situi doping method.

In some embodiments, the kind and concentration of dopant used for doping the polysilicon layer 130 may be varied according to the NMOS and PMOS regions in which the polysilicon layer 130 is formed. The conduction type and work function of the polysilicon layer 130 may be determined by the kind and concentration of dopant. The polysilicon layer 130 is patterned to form a gate electrode 135 (block 60).

According to an embodiment of the present invention, an upper conductive layer 140 may be formed on the polysilicon layer 130 before the polysilicon layer 130 is patterned. The upper conductive layer 140 may be formed of a metal silicide such as, for example, a tungsten silicide and/or a cobalt silicide. In some embodiments, the upper conductive layer 140 may be formed of metal such as tungsten.

After the gate electrode 135 is formed, impurity regions 150 may be formed in the semiconductor substrate 100 using the gate electrode 135 as a mask. The impurity regions 150 may be used as source/drain electrodes of a MOSFET. In some embodiments, the impurity regions 150 may have different conduction types according to the NMOS and PMOS regions. For example, the conduction type of an impurity region formed in the NMOS region may be n-type, and the conduction type of an impurity region formed in the PMOS region may be p-type.

In some embodiments, the gate electrode 135 formed of polysilicon may be formed on the gate insulation layer 110. As described above, the type and concentration of dopant used for doping the polysilicon layer 130 may be adjusted according to the NMOS and PMOS regions in which the polysilicon layer 130 is formed. In this manner, technical requirements (e.g., conductive type and work f unction) of gate electrodes of an NMOS-FET and a PMOS-FET may be easily satisfied.

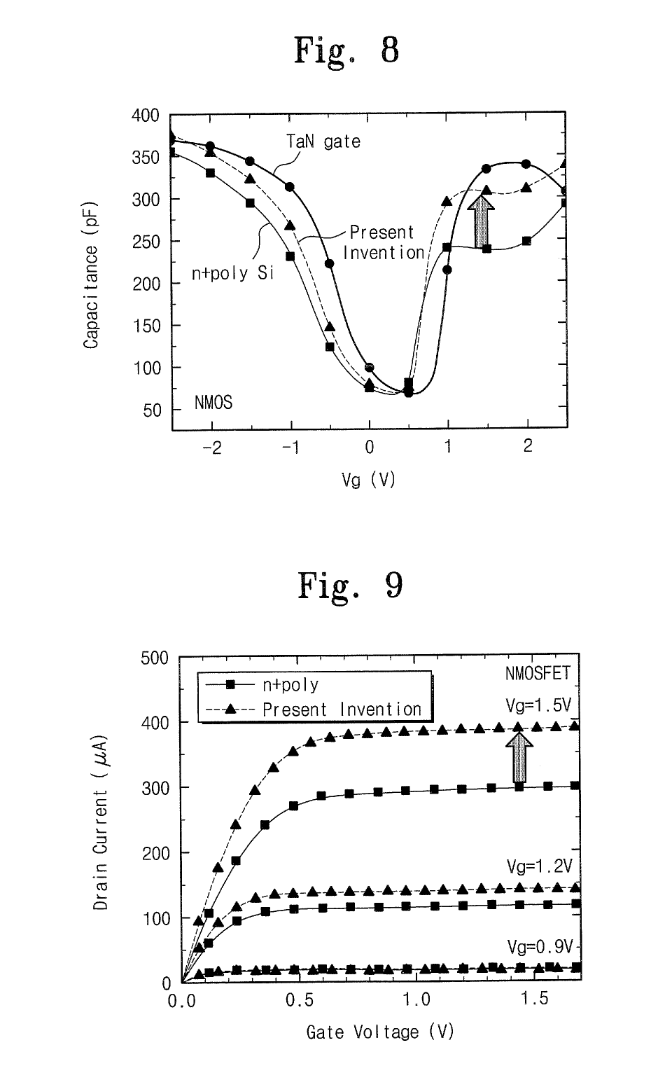

In some embodiments, the metallic residue 125 may be interposed between the gate electrode 135 and the gate insulation layer 110. In some embodiments, the metallic residue 125 may cover 1% to 100% of the top area of the gate insulation layer 110 as described in FIGS. 7A through 7C. The metallic residue 125 may be formed in this manner to reduce depletion of the gate electrode 135 formed of polysilicon. A reduction of depletion may be confirmed from capacitance-voltage (C-V) curve of FIG. 8 that results from the measurement of MOS capacitance.

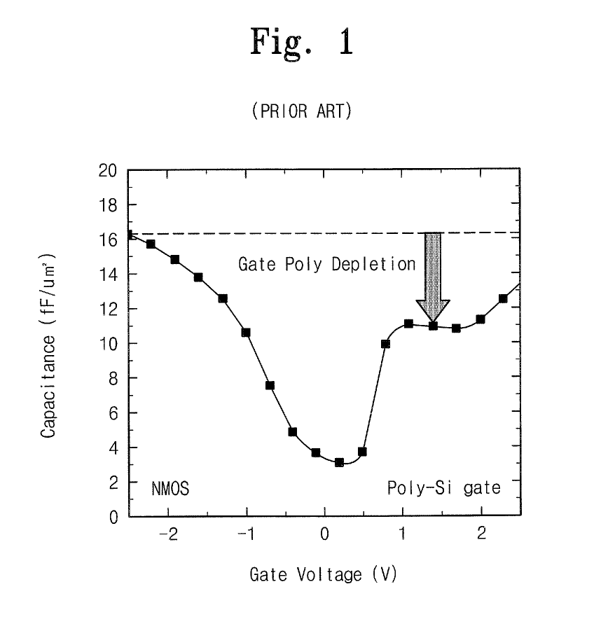

For example, referring to FIG. 8, when n+ polysilicon was used for a gate electrode, gate depletion increased, as illustrated in FIG. 1. Although when TaN was used for a gate electrode, gate depletion was reduced, the C-V curve was shifted as compared with the C-V curve of the device with the n+ polysilicon gate electrode. The shifting of the TaN curve may be due to a difference of work function between TaN and n+ polysilicon.

Although the C-V curve of a MOS-FET (refer to FIG. 6) fabricated according to some embodiments of the present invention was similar to the C-V curve of the device with the n+ polysilicon gate electrode, gate depletion was reduced to a level similar to the device with the TaN gate electrode. By reducing gate depletion, current-voltage characteristics of a semiconductor device may be improved as shown in FIG. 9.

Referring to FIG. 9, the saturation current of a MOS-FET of some embodiments of the present invention was increased by 30% to 40% as compared with a MOS-FET having an n+ polysilicon gate electrode. In the experiment of FIG. 9, the MOS-FET embodiment sample has substantially the same structure as the comparison sample except for a metallic residue 125 formed between a gate insulation layer 110 and a gate electrode 135. In this manner, an increase of saturation current may result from the reduction of gate depletion, as illustrated in FIG. 8.

In some embodiments, after a gate metal layer is formed on a gate insulation layer, the gate metal layer may be selectively removed by etching to form a metallic residue. A polysilicon layer may then be formed on the gate insulation layer including the metallic residue. The polysilicon layer may be used for gate electrodes. In this regard, gate electrodes of an NMOS-FET and a PMOS-FET may have optimized work functions. Further, formation of depletion layers at the polysilicon gate electrodes may be prevented by virtue of the metallic residue. As a result, the electrical characteristics of a MOS-FET of embodiments described herein may be improved, as shown in FIG. 9.

Although the present invention has been described in terms of specific embodiments, the present invention is not intended to be limited by the embodiments described herein. Thus, the scope may be determined by the following claims.

What is claimed is:

1. A method of fabricating a semiconductor device, the method comprising:
forming a gate insulation layer on a semiconductor substrate;
forming a metal layer on the gate insulation layer;
etching the metal layer to leave a metallic residue on the gate insulation layer monitoring an etch by-product to detect an etch endpoint for stopping the etching; and
forming a polysilicon layer on the gate insulation layer having the metallic residue.

2. The method of claim 1, wherein etching the metal layer comprises leaving 1% to 100% of a top area of the gate insulation area with the metallic residue.

3. The method of claim 1, wherein etching the metal layer comprises leaving metallic residue islands spaced apart from each other to expose a top surface of the gate insulation layer.

4. The method of claim 1, wherein etching the metal layer comprises defining a plurality of openings in the metallic residue through which a top surface of the gate insulation layer is exposed.

5. The method of claim 1, wherein etching the metal layer comprises leaving the metallic residue in a thickness of about 2 Å to about 10 Å on a top surface of the gate insulation layer.

6. The method of claim 1, further comprising: prior to etching the metal layer, heat-treating the metal layer to form an interface metal layer between the metal layer and the gate insulation layer, the interface metal layer having a chemical composition ratio different from that of the metal layer,
wherein the interface metal layer is formed by a reaction between the metal layer and the gate insulation layer during the heat-treatment.

7. The method of claim 1, wherein forming the metal layer comprises depositing one of TaN, WN, TiN, Ta, W, Ti, Ru, HfN, HfSiN, TiSiN, TaSiN, and HfAIN on the gate insulation layer using one of PVD. (physical vapor deposition), CVD (chemical vapor deposition), and ALD (atomic layer deposition).

8. The method of claim 1, wherein the semiconductor substrate comprises an NMOS (n-type metal oxide silicon) region and a PMOS (p-type metal oxide silicon) region, and
forming the polysilicon layer comprises implanting first and second dopants into the NMOS and PMOS regions, respectively.

9. The method of claim 8, wherein the first dopants implanted into the NMOS comprise a first doping concentration, wherein the second dopants implanted into PMOS regions comprise a second doping concentration, and wherein the first dopant concentration is different from the second doping concentration.

10. The method of claim 1, further comprising: after forming the polysilicon layer,
forming an upper conductive layer on the polysilicon layer;
patterning the upper conductive layer and the polysilicon layer to form a gate electrode; and
forming drain/source regions in the semiconductor substrate at both sides of the gate electrode,
wherein the upper conductive layer is formed of a silicide layer or an upper metal layer.

11. A semiconductor device, comprising:
a semiconductor substrate including an NMOS region and a PMOS region;
polysilicon electrodes disposed on the semiconductor substrate in the NMOS and PMOS regions;
a gate insulation layer disposed between the semiconductor substrate and the polysilicon electrodes; and
a metallic residue disposed between the gate insulation layer and the polysilicon electrodes.

12. The semiconductor device of claim 11, wherein the metallic residue covers 1% to 100% of a top area of the gate insulation layer.

13. The semiconductor device of claim 11, wherein the metallic residue comprises islands that are spaced apart from each other to expose a top surface of the gate insulation layer.

14. The semiconductor device of claim 11, wherein the metallic residue comprises a plurality of openings through which a top surface of the gate insulation layer is exposed.

15. The semiconductor device of claim 11, wherein the metallic residue covers a top surface of the gate insulation layer to a thickness of 2 Å to 10 Å.

16. The semiconductor device of claim 11, wherein the metallic residue is formed of a material selected from the group consisting of TaN, WN, TiN, Ta, W, Ti, Ru, HfN, HfSiN, TiSiN, TaSiN, and HfAIN.

17. The semiconductor device of claim 11, wherein the metallic residue is formed by reacting the gate insulation layer with a material selected from the group consisting of TaN, WN, TiN, Ta, W, Ti, Ru, HfN, HfSiN, TiSiN, TaSiN, and HfAIN.

18. The semiconductor device of claim 11, wherein the polysilicon electrode formed in the NMOS region comprises a first dopant type and a first concentration, wherein the polysilicon electrode formed in the PMOS region comprises a second dopant type and a second dopant concentration, wherein the first dopant type is different from the second dopant type, and wherein the first dopant concentration is different from the second dopant concentration.
